(19) United States
(12) Patent Application Publication
(10) Pub. No.: US 2021/0119166 A1
(43) Pub. Date: Apr. 22, 2021

(54) ORGANIC LIGHT EMITTING DIODE DISPLAY PANEL AND DISPLAY DEVICE

(71) Applicant: TCL CHINA STAR OPTOELECTRONICS TECHNOLOGY CO., LTD., Shenzhen, Guangdong (CN)

(72) Inventors: Yuanchun WU, Shenzhen, Guangdong (CN); Shibo Jiao, Shenzhen, Guangdong (CN); Yang Liu, Shenzhen, Guangdong (CN)

(21) Appl. No.: 16/618,803

(22) PCT Filed: Nov. 13, 2019
(86) PCT No.: PCT/CN2019/117756

§ 371 Date: Dec. 3, 2019

(30) Foreign Application Priority Data
Oct. 22, 2019 (CN) 201911005358.2

(51) Int. Cl. H01L 51/50; H01L 51/00

(52) U.S. Cl. CPC H01L 51/5016; H01L 51/0059; H01L 2251/5376; H01L 51/5024; H01L 51/504

(57) ABSTRACT

An OLED display panel and a display device are provided. The OLED display panel includes doped light emitting layers formed by doping the same main blue fluorescent luminescent material with the same secondary thermally activated delayed fluorescence material. A doping concentration of the secondary material in a first doped light emitting layer and a doping concentration of the secondary material in a second doped light emitting layer are different. It is advantageous for different light emitting layers to emit different wavelengths so as to realize generating multiple electroluminescence peaks, broaden the luminescence spectrum, improve a color rendering index, and thus achieve the effect of simplifying a light emitting layer structure.

### FIELD OF INVENTION

This disclosure relates to display technology, and more particularly, to an OLED display panel and a display device.

### BACKGROUND OF INVENTION

White organic light-emitting devices (OLEDs) are a novel light source technology, have the advantages of self-luminescence, high efficiency, surface light source, soft lighting, and so on, and meet the requirements of energy conservation, low-carbon environmental protection, and green lifestyle in the world at present. Organic light-emitting devices currently have shown great potential in the field of flat panel display and solid-state lighting. A color rendering index is an evaluation index indicative of an ability of a light source material itself expressing colors. The closer the color rendering index is to 100, the better the color rendering of the light source is. Solar light has a very broad spectrum, especially in a visible wavelength range. The color rendering index of solar light is close to 100. Therefore, in order to improve a white light quality of white OLEDs, it is necessary to broaden the luminescence spectrum and to increase the color rendering index.

Generally, in a white light OLED device, a plurality of luminescent dyes are doped in a main material to form a single-layer luminescent layer structure, or each of the luminescent dyes is doped in the same or different elements to form a multi-layer luminescent layer structure, thereby achieving white light devices with high performance. However, this design makes a structure of the device very complicated, and greatly increases the complexity of the preparation process. Moreover, reproducibility in the preparation process is not high, and the production costs are increased.

Therefore, it is necessary to solve the drawback that the complicated structure of the conventional luminescent layer.

### SUMMARY OF INVENTION

An object of the disclosure is to provide an organic light-emitting diode (OLED) display panel and a display device to solve the technical problem of the complicated structure of the conventional luminescent layer.

In order to achieve the above object, the disclosure provides an OLED panel. The OLED display panel comprises a substrate, a driving circuit layer disposed on the substrate, and a light emitting functional layer disposed on the driving circuit layer.

Besides, a light emitting layer of the light emitting functional layer comprises doped light emitting layers, a main material of the doped light emitting layers comprises a blue fluorescent luminescent material, a secondary material of the doped light emitting layers comprises a thermally activated delayed fluorescence material, the doped light emitting layers comprise a first doped light emitting layer and a second doped light emitting layer, which are disposed in laminations. A doping concentration of the secondary material in the first doped light emitting layer and a doping concentration of the secondary material in the second doped light emitting layer are different.

In the OLED display panel of the embodiment of the disclosure, a triplet exciton energy level of the blue fluorescent luminescent material is higher than a singlet exciton energy level and a triplet exciton energy level of the thermally activated delayed fluorescence material.

In the OLED display panel of the embodiment of the disclosure, the blue fluorescent luminescent material is composed one of a stilbene derivative, a tristyrene, a tetrastyrene derivative, a carbazole derivative, boron, and a beryllium derivative.

In the OLED display panel of the embodiment of the disclosure, a molecular structure of the thermally activated delayed fluorescence material comprises an electron donor group and an electron acceptor group. The electron donor group is selected from one or a mixture of two or more of a phenothiazine group, a triphenylamine group, a carbazole group, and an acridinium group. The electron acceptor group is selected from one of benzophenone group, diphenyl sulfone group, phthalonitrile group, triphenyltriazine group, phenyl phosphine oxide group, oxathiazin oxidation group, and thioxanthone group.

In the OLED display panel of the embodiment of the disclosure, the doped light emitting layer comprises a third doped light emitting layer, and the third doped light emitting layer is disposed on the second doped light emitting layer.

In the OLED display panel of the embodiment of the disclosure, a doping concentration of the secondary material in each of the first doped light emitting layer and the third doped light emitting layer is from 30% to 90%, and a doping concentration of the secondary material in the second doped light emitting layer is 1% to 10%.

In the OLED display panel of the embodiment of the disclosure, a doping concentration of the secondary material in each of the first doped light emitting layer and the third doped light emitting layer is from 1% to 10%, and a doping concentration of the secondary material in the second doped light emitting layer is from 30% to 90%.

In the OLED display panel of the embodiment of the disclosure, the doped light emitting layer comprises a fourth doped light emitting layer, and the fourth doped light emitting layer is disposed on the third doped light emitting layer.

In the OLED display panel of the embodiment of the disclosure, a doping concentration of the secondary material in each of the first doped light emitting layer and the third doped light emitting layer is from 30% to 90%, and a doping concentration of the secondary material in each of the second doped light emitting layer and the fourth doped light emitting layer is from 1% to 10%.

In the OLED display panel of the embodiment of the disclosure, a doping concentration of the secondary material in each of the first doped light emitting layer and the third doped light emitting layer is from 1% to 10%, and a doping concentration of the secondary material in each of the second doped light emitting layer and the fourth doped light emitting layer is from 30% to 90%.

The disclosure further provides a display device comprising the OLED display panel mentioned above. The OLED display panel comprises a substrate, a driving circuit layer disposed on the substrate, and a light emitting functional layer disposed on the driving circuit layer.

Besides, a light emitting layer of the light emitting functional layer comprises doped light emitting layers, a main material of the doped light emitting layers comprises a blue fluorescent luminescent material, a secondary material of the doped light emitting layers comprises a thermally activated delayed fluorescence material, the doped light emitting layers comprise a first doped light emitting layer and a second doped light emitting layer, which are disposed in laminations. A doping concentration of the secondary material in the first doped light emitting layer and a doping concentration of in the secondary material the second doped light emitting layer are different.

In the display device of the embodiment of the disclosure, a triplet exciton energy level of the blue fluorescent luminescent material is higher than a singlet exciton energy level and a triplet exciton energy level of the thermally activated delayed fluorescence material.

In the display device of the embodiment of the disclosure, the blue fluorescent luminescent material is composed one of a stilbene derivative, a tristyrene, a tetrastyrene derivative, a carbazole derivative, boron, and a beryllium derivative.

In the display device of the embodiment of the disclosure, a molecular structure of the thermally activated delayed fluorescence material comprises an electron donor group and an electron acceptor group. The electron donor group is selected from one or a mixture of two or more of a phenothiazine group, a triphenylamine group, a carbazole group, and an acridinium group. The electron acceptor group is selected from one of benzophenone group, diphenyl sulfone group, phthalonitrile group, triphenyltriazine group, phenyl phosphine oxide group, oxathiazin oxidation group, and thioxanthone group.

In the display device of the embodiment of the disclosure, the doped light emitting layer comprises a third doped light emitting layer, and the third doped light emitting layer is disposed on the second doped light emitting layer.

In the display device of the embodiment of the disclosure, a doping concentration of the secondary material in each of the first doped light emitting layer and the third doped light emitting layer is from 30% to 90%, and a doping concentration of the secondary material in the second doped light emitting layer is 1% to 10%.

In the display device of the embodiment of the disclosure, a doping concentration of the secondary material in each of the first doped light emitting layer and the third doped light emitting layer is from 1% to 10%, and a doping concentration of the secondary material in the second doped light emitting layer is from 30% to 90%.

In the display device of the embodiment of the disclosure, the doped light emitting layer comprises a fourth doped light emitting layer, and the fourth doped light emitting layer is disposed on the third doped light emitting layer.

In the display device of the embodiment of the disclosure, a doping concentration of the secondary material in each of the first doped light emitting layer and the third doped light emitting layer is from 30% to 90%, and a doping concentration of the secondary material in each of the second doped light emitting layer and the fourth doped light emitting layer is from 1% to 10%.

In the display device of the embodiment of the disclosure, a doping concentration of the secondary material in each of the first doped light emitting layer and the third doped light emitting layer is from 1% to 10%, and a doping concentration of the secondary material in each of the second doped light emitting layer and the fourth doped light emitting layer is from 30% to 90%.

The technical effects are as follows. The disclosure provides a display panel and a display device. The light emitting layer of the light emitting functional layer comprises doped light emitting layers. A main material of the doped light emitting layers comprises a blue fluorescent luminescent material, and a secondary material of the doped light emitting layers comprises a thermally activated delayed fluorescence material. The doped light emitting layers comprise a first doped light emitting layer and a second doped light emitting layer, which are disposed in laminations, and a doping concentration of the secondary material in the first doped light emitting layer and a doping concentration of the secondary material in the second doped light emitting layer are different. In this disclosure, the doped light emitting layer is designed as a structure comprising secondary materials in multiple layers with different doping concentrations and alternate high and low doping concentrations, to control the energy transfer between the luminescent materials. It is advantageous for different light emitting layers to emit light with different wavelengths and to achieve multiple electroluminescence peaks. Moreover, the luminescence spectrum is broadened and the color rendering index is increased. Thus, the purposes of simplifying the light emitting layer structure and reducing production costs are achieved.

### DESCRIPTION OF DRAWINGS

In order to clearly illustrate the embodiments of the present disclosure or the technical solutions in the prior art, the following briefly introduces the accompanying drawings used in the embodiments. Obviously, the drawings in the following description merely show some of the embodiments of the present disclosure. As regards one of ordinary skill in the art, other drawings can be obtained in accordance with these accompanying drawings without making creative efforts.

FIG. 1 is a schematic diagram of a first structure of an OLED display panel according to an embodiment of the disclosure.

FIG. 2 is a schematic diagram of a second structure of an OLED display panel according to an embodiment of the disclosure.

FIG. 3 is a schematic diagram of an emission spectrum of a secondary doped material according to a first embodiment of the disclosure.

FIG. 4 is a schematic diagram of a third structure of an OLED display panel according to an embodiment of the disclosure.

FIG. 5 is a second schematic diagram of an emission spectrum of a secondary doped material according to a second embodiment of the disclosure.

### DETAILED DESCRIPTION OF PREFERRED EMBODIMENTS

This description of the exemplary embodiments is intended to be read in connection with the accompanying drawings, which are to be considered part of the entire written description. In the description, terms such as “lower”, “upper”, “front”, “behind”, “left”, “right”, “inside”, “outside”, and “side”, as well as derivatives thereof, should be construed to refer to the orientation as then described or as shown in the drawing under discussion. The elements mentioned in the disclosure, such as the first, second, etc., are only to better distinguish and express different components. Referring to the drawings of the disclosure, similar elements are labeled with the same number.

The embodiments of the disclosure can solve the technical problem of the complicated structure of the conventional luminescent layer.

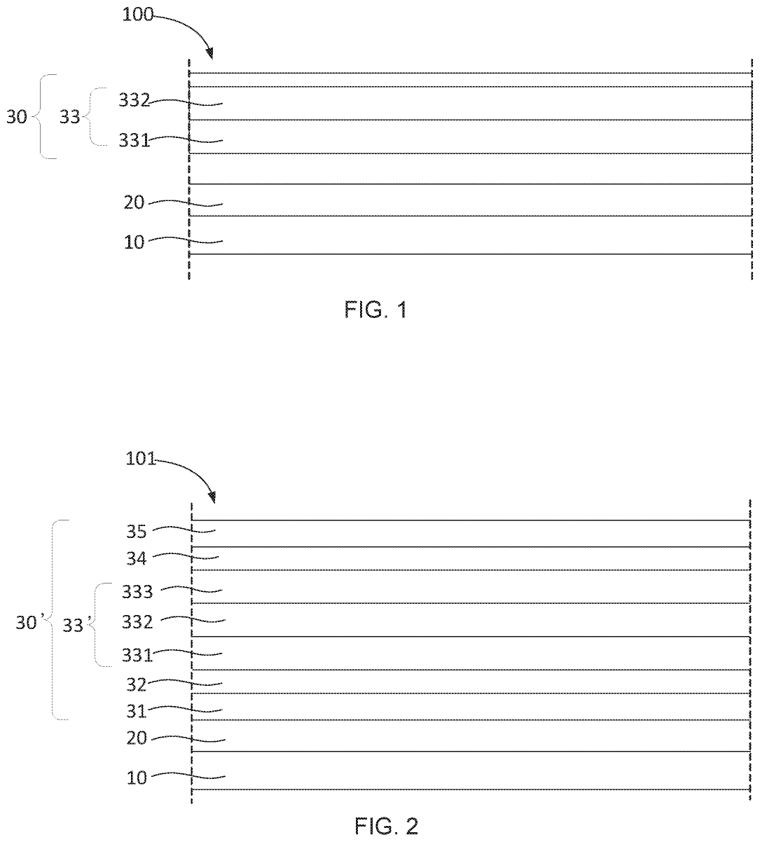

The disclosure provides an OLED panel 100, as shown in FIG. 1. The OLED display panel comprises a substrate 10, a driving circuit layer 20 disposed on the substrate 10, and a light emitting functional layer 30 disposed on the driving circuit layer 20.

Besides, a light emitting layer of the light emitting functional layer 30 comprises doped light emitting layers 33, a main material of the doped light emitting layers comprises a blue fluorescent luminescent material, and a secondary material of the doped light emitting layers comprises a thermally activated delayed fluorescence material. The doped light emitting layers comprise a first doped light emitting layer 331 and a second doped light emitting layer 332, which are disposed in laminations. A doping concentration of the secondary material in the first doped light emitting layer 331 and a doping concentration of the secondary material in the second doped light emitting layer 332 are different.

Specifically, luminescence peaks of the thermally activated delayed fluorescence materials are very sensitive to the doping concentrations. When the doping concentrations of the thermally activated delayed fluorescence materials are gradually increased, the luminescence spectrum can exhibit significant changes, such as the luminescent color can be significantly changed from yellow light to orange light or even to red light.

Specifically, a triplet exciton energy level of the blue fluorescent luminescent material is higher than a singlet exciton energy level and a triplet exciton energy level of the thermally activated delayed fluorescence material. Therefore, the exciton loss is reduced through the energy transfer between the blue fluorescent luminescent material and the thermally activated delayed fluorescence material. Moreover, an exciton utilization rate of the thermally activated delayed fluorescence material can theoretically achieve 100%. By combining the blue fluorescent luminescent material and the thermally activated delayed fluorescence material to prepare the doped light emitting layer, the amount of luminescent materials can be reduced, thereby reducing material costs.

In one embodiment, the substrate 10 comprises a certain ability to penetrate water vapor and oxygen, and comprises good surface flatness. The substrate can be a glass or a flexible substrate, and the flexible substrate is made of one of polyesters or polyphthalimide compounds or thinner metals.

In one embodiment, the blue fluorescent luminescent material is one of a stilbene derivative, triphenylene, a tetrastyrene derivative, a carbazole derivative, boron and a beryllium derivative.

In one embodiment, the thermally activated delayed fluorescence (TADF) material has a small difference between a singlet energy level and a triplet energy level, such that a reverse intersystem-crossing from a triplet electron system to a singlet electron system may occur at normal temperature, thereby theoretically reaching 100% of the exciton utilization.

In one embodiment, a molecular structure of the thermally activated delayed fluorescent material comprises an electron donor group and an electron acceptor group. The electron donor group is selected from one or a mixture of two or more of a phenothiazine group, a triphenylamine group, a carbazole group, and an acridinium group. The electron acceptor group is selected from one of benzophenone group, diphenyl sulfone group, phthalonitrile group, triphenyltriazine group, phenyl phosphine oxide group, oxathiazin oxidation group, and thioxanthone group.

In one embodiment, referring to FIG. 2, the light emitting function layer 30′ of the OLED display panel 101 includes an anode layer 31, a hole transporting layer 32, a doped light emitting layer 33′, an electron transporting layer 34, and a cathode layer 35.

In one embodiment, the doped light emitting layer 33′ is formed by doping the same type of the main blue fluorescent luminescent material with the same type of the secondary thermally activated delayed fluorescence material.

In one embodiment, the doped light emitting layer 33′ includes a first doped light emitting layer 331, a second doped light emitting layer 332, and a third doped light emitting layer 333, which are disposed in laminations. A doping concentration of the secondary material in each of the first doped light emitting layer 331 and the third doped light emitting layer 333 is from 30% to 90%, and a doping concentration of the secondary material in the second doped light emitting layer 332 is from 1% to 10%.

In one embodiment, a doping concentration of the secondary material in the first doped light emitting layer 331 is 90%, a doping concentration of the secondary material in the third doped light emitting layer 333 is 50%, and a doping concentration of the secondary material in the second doped light emitting layer 332 is 10%.

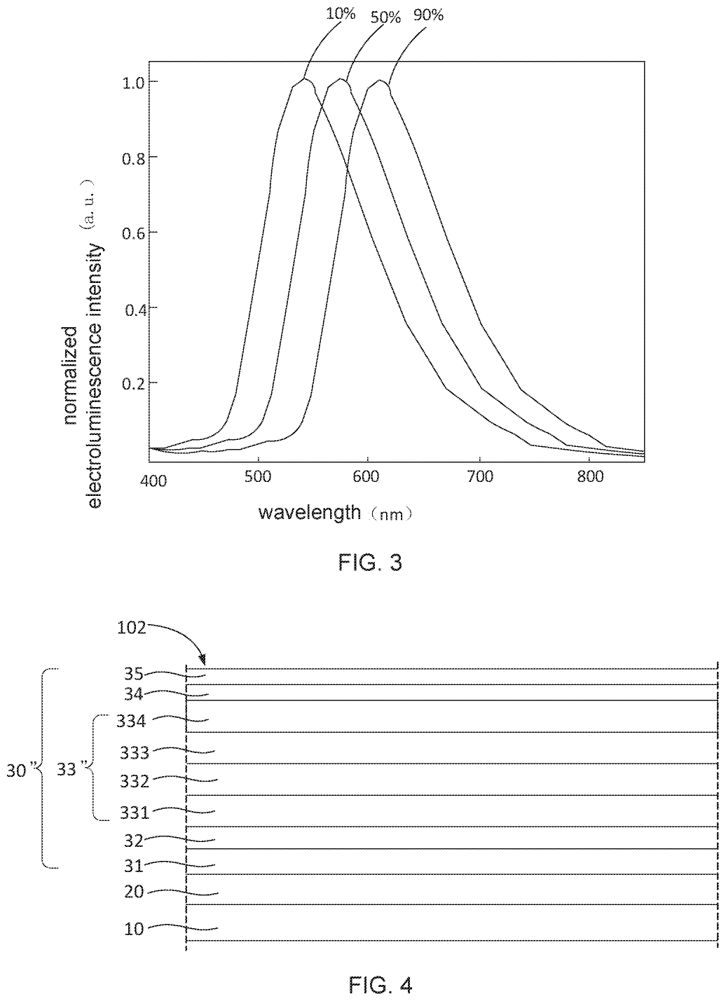

In one embodiment, referring to FIG. 3, an electroluminescence spectrum of the thermally activated delayed fluorescence materials at different doping concentrations is shown. The doping concentrations shown in the figure are the mass ratios of the doping of the secondary thermally activated fluorescence materials. In this embodiment, a doping concentration of the secondary material in the first doped light emitting layer 331 is preferably 90%, a doping concentration of the secondary material in the third doped light emitting layer 333 is preferably 50%, and a doping concentration of the secondary material in the second doped light emitting layer 332 is preferably 10%. It can be seen from FIG. 3 that the doped light emitting layer is doped with different concentrations of the secondary-doped thermally activated delayed fluorescence materials, so that different light emitting layers can emit different wavelengths to realize multiple electroluminescence peaks and broaden the luminescence spectrum.

In one embodiment, the electron transporting layer is made of one or more of the group consisting of a metal complex, an oxadiazole compound, a quinoxaline compound, a nitrogen-containing heterocyclic compound, a phosphine oxide compound, an anthracene compound, a silicone material, an organic boron material, and an organic sulfur material. Besides, the metal complex is 8-hydroxyquinoline aluminum, bis(2-methyl-8-hydroxyquinoline)(p-phenylphenol)aluminum, lithium 8-hydroxyquinolate, bis (10-hydroxybenzo[h]quinoline) beryllium, or bis [2-(2-hydroxyphenyl-1)-pyridine] beryllium. The oxadiazole compound is 2-(4-diphenyl)-5-(4-tert-butylphenyl)-1,3,4-oxadiazole 18 or 1,3-bis[2-(4-) Butylbenzene)-1,3,4-oxadiazol-5-yl]benzene. The nitrogen-containing heterocyclic compound is 1,3,5-(tri-N-phenyl-2-benzimidazole-2)benzene 41,4,7-biphenyl-1,10-phenanthroline, 2, 9-Dimethyl-4,7-biphenyl-1,10-phenanthroline, 3-(4-diphenyl)-4-benzene-5-tert-butylbenzene-1,2,4-Benzotriazole, 3,5,3″,5″-tetrazole-[1,1′;3′,1″]terphenyl, 3-(diphenylphosphoryl chloride)-9-benzene-9H-carbazole, 3,6-bis(diphenylphosphoryl chloride)-9-benzene-9H-carbazole. The phosphine oxide compound is bis(2-(diphenylphosphino)benzene)ether oxide or 2,8-bis(xylylene phosphate) sulfonium. The anthracene compounds are 9,10-di-(2-naphthyl) anthracene, organic boron materials are tris (2,4,6-trimethyl-3-(pyridine-3-yl) benzene) borane, and the organic sulfur materials are 2,8-di (xylene phosphoric acid) thiofluorene.

In one embodiment, the cathode is usually a metal material with low work function, such as lithium, magnesium, calcium, strontium, aluminum, indium and other metals with low work function, or an alloy thereof with copper, gold, silver, or the cathode is composed of a thin buffer insulating layer (such as LiF, MgF₂) and the aforementioned metals or alloys.

In one embodiment, the difference between this embodiment and the above embodiments is described as follow. The first doped light emitting layer 331, the second doped light emitting layer 332, and the third doped light emitting layer 333 of the doped light emitting layer comprises different doping concentrations. The doping concentration of the secondary material in each of the first doped light emitting layer 331 and the third doped light emitting layer 333 is from 1% to 10%, and the doping concentration of the secondary material in the second doped light emitting layer 332 is from 30% to 90%. For other descriptions, refer to the above embodiments, and details are not described herein again.

In one embodiment, referring to FIG. 4, the light emitting function layer 30″ of the OLED display panel 102 includes an anode layer 31, a hole transporting layer 32, a doped light emitting layer 33″, an electron transporting layer 34, and a cathode layer 35.

Referring to FIG. 4, the doped light emitting layer 33″ includes a first doped light emitting layer 331, a second doped light emitting layer 332, a third doped light emitting layer 333 and a fourth doped light emitting layer 334. A doping concentration of the secondary material in each of the first doped light emitting layer 331 and the third doped light emitting layer 333 is from 30% to 90%, and a doping concentration of the secondary material in each of the second doped light emitting layer 332 and the fourth doped light emitting layer 334 is from 1% to 10%.

In another embodiment, a doping concentration of the secondary material in the first doped light emitting layer 331 is 80%, a doping concentration of the secondary material in the third doped light emitting layer 333 is 30%, a doping concentration of the secondary material in the second doped light emitting layer 332 is 8%, and a doping concentration of the secondary material in the fourth doped light emitting layer 332 is 1%.

Specifically, luminescence peaks of the thermally activated delayed fluorescence materials are very sensitive to the doping concentrations. When the doping concentrations of the thermally activated delayed fluorescence materials are gradually increased, the luminescence spectrum can exhibit significant changes, such as the luminescent color can be significantly changed from yellow light to orange light or even to red light.

Specifically, the anode layer 31 generally requires good electrical conductivity, visible light transparency, and a high work function. The anode layer is usually an inorganic metal oxide (such as indium tin oxide, ITO), an organic conductive polymer (such as PEDOT:PSS), or metal materials with high work function (such as gold, copper, silver, platinum).

Specifically, a material of the hole transporting layer 32 is one or a mixture of two or more of a carbazole compound, an aromatic triamine compound or a star-shaped triphenylamine compound. The carbazole compound may be 1,3-bis(carbazol-9-yl)benzene (MCP), 4,4′,4″-tris(carbazol-9-yl)triphenylamine (TCTA), 4,4′-Bis(oxazol-9-yl)biphenyl (CBP) or 3,3-bis(9H-carbazole-9-yl)biphenyl (mCBP). The aromatic triamine compound may be bis-[4-(N,N-toluene-amino)-phenyl]cyclohexane (TAPC). The star-shaped triphenylamine compounds can be a mixture of one or more star-shaped triphenylamine compounds containing phenyl group (TDAB series), triphenylamine (PTDATA series) or 1,3,5-triphenylbenzene (TDAPB series) at the molecular center.

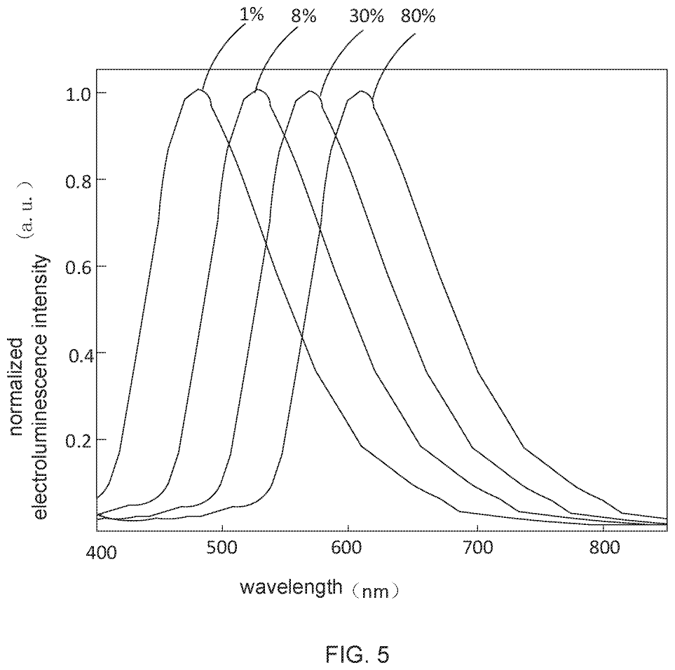

Referring to FIG. 5, an electroluminescence spectrum of the thermally activated delayed fluorescence materials at different doping concentrations is shown. The doping concentrations shown in FIG. 5 are the mass ratios of the doping of the secondary thermally activated fluorescence materials. In this embodiment, a doping concentration of the secondary material in the first doped light emitting layer is preferably 80%, a doping concentration of the secondary material in the second doped light emitting layer is preferably 8%, a doping concentration of the secondary material in the third doped light emitting layer is preferably 30%, and a doping concentration of the secondary material in the fourth doped light emitting layer is preferably 1%. It can be seen from FIG. 5 that the doped light emitting layer is doped with different concentrations of the secondary-doped thermally activated delayed fluorescence materials, so that different light emitting layers can emit different wavelengths to realize multiple electroluminescence peaks and broaden the luminescence spectrum.

In another embodiment, the difference between this embodiment and the above embodiments is described as follow. The first doped light emitting layer 331, the second doped light emitting layer 332, the third doped light emitting layer 333, and the fourth doped light emitting layer 334 of the doped light emitting layer comprises different doping concentrations. The doping concentration of the secondary material in each of the first doped light emitting layer 331 and the third doped light emitting layer 333 is from 1% to 10%, and the doping concentration of the secondary material in each of the second doped light emitting layer 332 and the fourth doped light emitting layer 334 is from 30% to 90%. For other descriptions, refer to the above embodiments, and details are not described herein again.

In one embodiment, the number of layers of the doped light emitting layer can also be disposed as more layers.

In one embodiment, the disclosure further provides a method for manufacturing an OLED display panel. The method comprises the following steps.

In a step S1, a substrate is provided, and the substrate is cleaned and dried.

In a step S2, a driving circuit layer is prepared. The driving circuit layer comprises a buffer layer, an active layer, a gate insulating layer, a gate layer, an interlayer insulating layer, a source drain layer, and a planarization layer sequentially laminated on the substrate.

In a step S3, a light emitting functional layer is prepared. The light emitting functional layer comprises an anode layer, a hole transporting layer, a doped light emitting layer, an electron transporting layer, and a cathode layer sequentially laminated on the driving circuit layer. Besides, the doped light emitting layer may be sequentially laminated according to requirements to prepare a double layer structure or a multi-layer structure of doped light emitting layers. For example, preparing a first doped light emitting layer, a second doped light emitting layer, a third doped light emitting layer, and a fourth doped light emitting layer are sequentially laminated.

In a step S4, an encapsulation layer is prepared. The substrate prepared by the above steps is encapsulated.

Specifically, in the step S3, the anode layer, the hole transporting layer, the doped light emitting layer, the electron transport layer and the cathode layer are directly prepared by a dry process sequentially, or after dilutions of organic solvents, sequentially formed on the substrate by a wet process. For example, the process comprises one or more methods of vacuum evaporation, ion beam deposition, ion plating, DC sputtering, RF sputtering, ion beam sputtering, ion beam assisted deposition, plasma enhanced chemical vapor deposition, High-density inductively coupled plasma source chemical vapor deposition, catalytic chemical vapor deposition, magnetron sputtering, electroplating, spin coating, dip coating, inkjet printing, roll coating, LB film.

Specifically, in the step S3, the doped light emitting layer is formed by doping the same type of the main material of the blue fluorescent luminescent material with the same type of the secondary material of the thermally activated delayed fluorescence material. The doping concentrations of the secondary material of the doped light emitting layers are different, such as a doping concentration of the secondary material in the first doped light emitting layer of the doped light emitting layer is preferably 70%, a doping concentration of the secondary material in the third doped light emitting layer is preferably 40%, a doping concentration of the secondary material in the second doped light emitting layer is preferably 9%, and a doping concentration of the secondary material in the fourth doped light emitting layer is preferably 2%.

In one embodiment, the disclosure further provides a display device comprising the OLED display panel mentioned above. The OLED display panel comprises a substrate, a driving circuit layer disposed on the substrate, and a light emitting functional layer disposed on the driving circuit layer.

Besides, a light emitting layer of the light emitting functional layer comprises doped light emitting layers, a main material of the doped light emitting layers comprises a blue fluorescent luminescent material, a secondary material of the doped light emitting layers comprises a thermally activated delayed fluorescence material, the doped light emitting layers comprise a first doped light emitting layer and a second doped light emitting layer, which are disposed in laminations. A doping concentration of the secondary material in the first doped light emitting layer and a doping concentration of in the secondary material the second doped light emitting layer are different.

In one embodiment, a triplet exciton energy level of the blue fluorescent luminescent material is higher than a singlet exciton energy level and a triplet exciton energy level of the thermally activated delayed fluorescence material.

In one embodiment, the blue fluorescent luminescent material is composed one of a stilbene derivative, a tristyrene, a tetrastyrene derivative, a carbazole derivative, boron, and a beryllium derivative.

In one embodiment, a molecular structure of the thermally activated delayed fluorescence material comprises an electron donor group and an electron acceptor group. The electron donor group is selected from one or a mixture of two or more of a phenothiazine group, a triphenylamine group, a carbazole group, and an acridinium group. The electron acceptor group is selected from one of benzophenone group, diphenyl sulfone group, phthalonitrile group, triphenyltriazine group, phenyl phosphine oxide group, oxathiazin oxidation group, and thioxanthone group.

In one embodiment, the doped light emitting layer comprises a third doped light emitting layer, and the third doped light emitting layer is disposed on the second doped light emitting layer.

In one embodiment, a doping concentration of the secondary material in each of the first doped light emitting layer and the third doped light emitting layer is from 30% to 90%, and a doping concentration of the secondary material in the second doped light emitting layer is from 1% to 10%.

In one embodiment, a doping concentration of the secondary material in each of the first doped light emitting layer and the third doped light emitting layer is from 1% to 10%, and a doping concentration of the secondary material in the second doped light emitting layer is from 30% to 90%.

In one embodiment, the doped light emitting layer comprises a fourth doped light emitting layer, and the fourth doped light emitting layer is disposed on the third doped light emitting layer.

In one embodiment, a doping concentration of the secondary material in each of the first doped light emitting layer and the third doped light emitting layer is from 30% to 90%, and a doping concentration of the secondary material in each of the second doped light emitting layer and the fourth doped light emitting layer is from 1% to 10%.

In the display device of the embodiment of the disclosure, a doping concentration of the secondary material in each of the first doped light emitting layer and the third doped light emitting layer is from 1% to 10%, and a doping concentration of the secondary material in each of the second doped light emitting layer and the fourth doped light emitting layer is from 30% to 90%.

The technical effects are as follows. The disclosure provides a display panel and a display device. The light emitting layer of the light emitting functional layer comprises doped light emitting layers. A main material of the doped light emitting layers comprises a blue fluorescent luminescent material, and a secondary material of the doped light emitting layers comprises a thermally activated delayed fluorescence material. The doped light emitting layers comprise a first doped light emitting layer and a second doped light emitting layer, which are disposed in laminations, and a doping concentration of the secondary material in the first doped light emitting layer and a doping concentration of the secondary material in the second doped light emitting layer are different. In this disclosure, the doped light emitting layer is designed as a structure comprising secondary materials in multiple layers with different doping concentrations and alternate high and low doping concentrations, to control the energy transfer between the luminescent materials. It is advantageous for different light emitting layers to emit light with different wavelengths and to achieve multiple electroluminescence peaks. Moreover, the luminescence spectrum is broadened and the color rendering index is increased. Thus, the purposes of simplifying the light emitting layer structure and reducing production costs are achieved.

This disclosure has been described with preferred embodiments thereof, and it is understood that many changes and modifications to the described embodiment can be carried out without departing from the scope and the spirit of the invention.

What is claimed is:

1. An OLED display panel, comprising:
a substrate;
a driving circuit layer disposed on the substrate; and
a light emitting functional layer disposed on the driving circuit layer;
wherein a light emitting layer of the light emitting functional layer comprises doped light emitting layers, a main material of the doped light emitting layers comprises a blue fluorescent luminescent material, a secondary material of the doped light emitting layers comprises a thermally activated delayed fluorescence material, the doped light emitting layers comprise a first doped light emitting layer and a second doped light emitting layer, which are disposed in laminations, and wherein a doping concentration of the secondary material in the first doped light emitting layer and a doping concentration of the secondary material in the second doped light emitting layer are different.

2. The OLED display panel according to claim 1, wherein a triplet exciton energy level of the blue fluorescent luminescent material is higher than a singlet exciton energy level and a triplet exciton energy level of the thermally activated delayed fluorescence material.

3. The OLED display panel according to claim 2, wherein the blue fluorescent luminescent material is composed one of a stilbene derivative, a tristyrene, a tetrastyrene derivative, a carbazole derivative, boron, and a beryllium derivative.

4. The OLED display panel according to claim 2, wherein a molecular structure of the thermally activated delayed fluorescence material comprises an electron donor group and an electron acceptor group, the electron donor group is selected from one or a mixture of two or more of a phenothiazine group, a triphenylamine group, a carbazole group, and an acridinium group, and the electron acceptor group is selected from one of benzophenone group, diphenyl sulfone group, phthalonitrile group, triphenyltriazine group, phenyl phosphine oxide group, oxathiazin oxidation group, and thioxanthone group.

5. The OLED display panel according to claim 1, wherein the doped light emitting layer comprises a third doped light emitting layer, and the third doped light emitting layer is disposed on the second doped light emitting layer.

6. The OLED display panel according to claim 5, wherein a doping concentration of the secondary material in each of the first doped light emitting layer and the third doped light emitting layer is from 30% to 90%, and a doping concentration of the secondary material in the second doped light emitting layer is from 1% to 10%.

7. The OLED display panel according to claim 5, wherein a doping concentration of the secondary material in each of the first doped light emitting layer and the third doped light emitting layer is from 1% to 10%, and a doping concentration of the secondary material in the second doped light emitting layer is from 30% to 90%.

8. The OLED display panel according to claim 5, wherein the doped light emitting layer comprises a fourth doped light emitting layer, and the fourth doped light emitting layer is disposed on the third doped light emitting layer.

9. The OLED display panel according to claim 8, wherein a doping concentration of the secondary material in each of the first doped light emitting layer and the third doped light emitting layer is from 30% to 90%, and a doping concentration of the secondary material in each of the second doped light emitting layer and the fourth doped light emitting layer is from 1% to 10%.

10. The OLED display panel according to claim 8, wherein a doping concentration of the secondary material in each of the first doped light emitting layer and the third doped light emitting layer is from 1% to 10%, and a doping concentration of the secondary material in each of the second doped light emitting layer and the fourth doped light emitting layer is from 30% to 90%.

11. A display device, comprising: an OLED display panel, wherein the OLED display panel comprises:
a substrate;
a driving circuit layer disposed on the substrate; and
a light emitting functional layer disposed on the driving circuit layer;
wherein a light emitting layer of the light emitting functional layer comprises doped light emitting layers, a main material of the doped light emitting layers comprises a blue fluorescent luminescent material, a secondary material of the doped light emitting layers comprises a thermally activated delayed fluorescence material, the doped light emitting layers comprise a first doped light emitting layer and a second doped light emitting layer, which are disposed in laminations, and wherein a doping concentration of the secondary material in the first doped light emitting layer and a doping concentration of the secondary material in the second doped light emitting layer are different.

12. The display device according to claim 11, wherein a triplet exciton energy level of the blue fluorescent luminescent material is higher than a singlet exciton energy level and a triplet exciton energy level of the thermally activated delayed fluorescence material.

13. The display device according to claim 12, wherein the blue fluorescent luminescent material is composed one of a stilbene derivative, a tristyrene, a tetrastyrene derivative, a carbazole derivative, boron, and a beryllium derivative.

14. The display device according to claim 12, wherein a molecular structure of the thermally activated delayed fluorescence material comprises an electron donor group and an electron acceptor group, the electron donor group is selected from one or a mixture of two or more of a phenothiazine group, a triphenylamine group, a carbazole group, and an acridinium group, and the electron acceptor group is selected from one of benzophenone group, diphenyl sulfone group, phthalonitrile group, triphenyltriazine group, phenyl phosphine oxide group, oxathiazin oxidation group, and thioxanthone group.

15. The display device according to claim 11, wherein the doped light emitting layer comprises a third doped light emitting layer, and the third doped light emitting layer is disposed on the second doped light emitting layer.

16. The display device according to claim 15, wherein a doping concentration of the secondary material in each of the first doped light emitting layer and the third doped light emitting layer is from 30% to 90%, and a doping concentration of the secondary material in the second doped light emitting layer is from 1% to 10%.

17. The display device according to claim 15, wherein a doping concentration of the secondary material in each of the first doped light emitting layer and the third doped light emitting layer is 1% to 10%, and a doping concentration of the secondary material in the second doped light emitting layer is from 30% to 90%.

18. The display device according to claim 15, wherein the doped light emitting layer comprises a fourth doped light emitting layer, and the fourth doped light emitting layer is disposed on the third doped light emitting layer.

19. The display device according to claim 18, wherein a doping concentration of the secondary material in each of the first doped light emitting layer and the third doped light emitting layer is from 30% to 90%, and a doping concentration of the secondary material in each of the second doped light emitting layer and the fourth doped light emitting layer is 1% to 10%.

20. The display device according to claim 18, wherein a doping concentration of the secondary material in each of the first doped light emitting layer and the third doped light emitting layer is from 1% to 10%, and a doping concentration of the secondary material in each of the second doped light emitting layer and the fourth doped light emitting layer is from 30% to 90%.
